(19) United States
(12) Patent Application Publication
(10) Pub. No.: US 2012/0050632 A1
(43) Pub. Date: Mar. 1, 2012

(54) DISPLAY APPARATUS HAVING QUANTUM DOT LAYER

(75) Inventor: HSI-HSIN SHIH, TAINAN CITY (TW)

(73) Assignee: CHI LIN TECHNOLOGY CO., LTD., TAINAN CITY (TW)

(21) Appl. No.: 13/217,522

(22) Filed: Aug. 25, 2011

Related U.S. Application Data
(60) Provisional application No. 61/378,651, filed on Aug. 31, 2010.

(51) Int. Cl. G02F 1/1368; H01L 27/15; B82Y 20/00

(52) U.S. Cl. 349/42; 257/13; 977/952; 257/E27.121

(57) ABSTRACT

The present invention relates to a display apparatus, which has a quantum dot layer. The quantum dot layer has a plurality of quantum dot blocks which comprise quantum dots and are arranged in a matrix. The quantum dots when excited by the light convert the light wavelength so as to determine the color of each pixel of an image. As a result, the color filter of prior art can be omitted. Compared with the luminescent efficiency of the display apparatus of prior art, the luminescent efficiency of the display apparatus of the present invention can be raised.

### BACKGROUND OF THE INVENTION

1. Field of the Invention

The present invention relates to a display apparatus, and more particularly, to a display apparatus having a quantum dot layer.

2. Description of the Related Art

FIG. 1 shows a schematic view of a conventional display apparatus. The display apparatus 1 includes a light source 11, a bottom polarizer 12, a display panel 10, a top polarizer 16. The light source 11, for example, a plurality of LEDs or CCFLs, or a back light module, is used to provide a light beam. The display panel 10 includes a thin film transistor (TFT) layer 13, a liquid crystal layer 14 and a color filter layer 15. The display panel 10 is disposed above the light source 11 to display an image, and a PCB (not shown) is used for driving the display panel 10. The thin film transistor (TFT) layer 13 and the color filter layer 15 face with each other, and the liquid crystal layer 14 is disposed between the thin film transistor (TFT) layer 13 and the color filter layer 15.

The thin film transistor (TFT) layer 13 has a plurality of TFTs arranged in a matrix. Each of the TFTs includes a source electrode, a gate electrode and a drain electrode. The source electrode is electrically connected to a data line, the gate electrode is electrically connected to a scan line, and the drain electrode is electrically connected to a pixel electrode. The pixel electrode includes an optically transparent and electrically conductive material. The TFTs of the thin film transistor (TFT) layer 13 are used to control the liquid crystal molecules of the liquid crystal layer 14 by the PCB.

The color filter layer 15 has a plurality of RGB color filters arranged in a matrix. The RGB color filters are used to filter the light beam that passes through the liquid crystal layer 14, so as to determine the colors of every pixels. The bottom polarizer 12 is attached to a bottom surface of the thin film transistor (TFT) layer 13, and the top polarizer 16 is attached to a top surface of the color filter layer 15. The bottom polarizer 12 and the top polarizer 16 are used to convert light polarization of the light beam.

The disadvantage of the display apparatus 1 is that the color filter layer 15 filters some light so that the output brightness of the display apparatus 1 will be reduced 67% of brightness of the light beam from the light source 11. That is, the luminescent efficiency is only 33%.

Therefore, it is necessary to provide a display apparatus having a quantum dot layer to solve the above problem.

### SUMMARY OF THE INVENTION

The present invention is directed to a display apparatus, which comprises a light source, a thin film transistor (TFT) layer, a liquid crystal layer, a bottom polarizer, a top polarizer and a quantum dot layer. The light source is used to provide a light beam. The thin film transistor (TFT) layer has a plurality of TFTs arranged in a matrix. The liquid crystal layer has a plurality of liquid crystal molecules, and is disposed on the thin film transistor (TFT) layer. The TFTs of the thin film transistor (TFT) layer are used to control the liquid crystal molecules of the liquid crystal layer. The bottom polarizer is attached to the bottom surface of the thin film transistor (TFT) layer, and is used to convert light polarization of the light beam. The top polarizer is attached to the top surface of the liquid crystal layer, and is used to convert light polarization of the light beam. The bottom polarizer, the thin film transistor (TFT) layer, the liquid crystal layer and the top polarizer are disposed above the light source to display an image, and the image has a plurality of pixels. The quantum dot layer is disposed above the top polarizer, and has a plurality of quantum dot blocks which comprise quantum dots and are arranged in a matrix, wherein the quantum dots when excited by light beam passing through the top polarizer convert the light wavelengths so as to determine the color of each pixel of the image.

The present invention is further directed to a display apparatus, which comprises an electrical controller layer, a light emitting layer and a quantum dot layer. The electrical controller layer has a plurality of pixels arranged in a matrix. The light emitting layer is used to provide a light beam. The light emitting layer is disposed above the electrical controller layer, and controlled by the electrical controller layer. The quantum dot layer is disposed above the light emitting layer to display an image, and the image has a plurality of pixels. The quantum dot layer has a plurality of quantum dot blocks which comprise quantum dots and are arranged in a matrix, wherein each pixel of the electrical controller layer corresponds to at least one quantum dot block. The quantum dots when excited by the light beam convert the light wavelength so as to determine the color of each pixel of the image.

The present invention is further directed to a display apparatus, which comprises an electrical controller layer and a quantum dot layer. The electrical controller layer has a plurality of pixels arranged in a matrix. The quantum dot layer is attached to the electrical controller layer to display an image, and the image has a plurality of pixels. The quantum dot layer has a plurality of quantum dot blocks which comprise quantum dots and are arranged in a matrix, wherein each pixel of the electrical controller layer corresponds to at least one quantum dot block. The quantum dots emit light when excited by the pixels of the electrical controller layer so as to determine the color of each pixel of the image.

As a result, the color filter of prior art can be omitted. Compared with the luminescent efficiency of the display apparatus of prior art, the luminescent efficiency of the display apparatus of the present invention is raised, says, 50% to 80%.

### BRIEF DESCRIPTION OF THE DRAWINGS

FIG. 1 is a schematic view of a conventional display apparatus;

FIG. 2 is a schematic view of a display apparatus according to a first embodiment of the present invention;

FIG. 3 is a schematic view of a display apparatus according to a second embodiment of the present invention; and

FIG. 4 is a schematic view of a display apparatus according to a third embodiment of the present invention.

### DETAILED DESCRIPTION OF THE INVENTION

FIG. 2 shows a schematic view of a display apparatus according to a first embodiment of the present invention. The display apparatus 2 comprises a light source 21, a bottom polarizer 22, a thin film transistor (TFT) layer 23, a liquid crystal layer 24, a top polarizer 26 and a quantum dot layer 27. The light source 21, for example, at least one LED or CCFL, or a back light module, is used to provide a light beam. The bottom polarizer 22, the thin film transistor (TFT) layer 23, the liquid crystal layer 24, the top polarizer 26 and the quantum dot layer 27 are disposed above the light source 21 to display an image, and the image has a plurality of pixels. A PCB (not shown) is used for driving the thin film transistor (TFT) layer 23. The liquid crystal layer 24 has a plurality of liquid crystal molecules and is disposed on the thin film transistor (TFT) layer 23.

The thin film transistor (TFT) layer 23 has a plurality of TFTs arranged in a matrix. Each of the TFTs includes a source electrode, a gate electrode and a drain electrode. The source electrode is electrically connected to a data line, the gate electrode is electrically connected to a scan line, and the drain electrode is electrically connected to a pixel electrode. The pixel electrode includes an optically transparent and electrically conductive material. The TFTs of the thin film transistor (TFT) layer 23 are used to control the liquid crystal molecules of the liquid crystal layer 24 by the PCB.

The bottom polarizer 22 is attached to the bottom surface of the thin film transistor (TFT) layer 23, and the top polarizer 26 is attached to the top surface of the liquid crystal layer 24. The bottom polarizer 22 and the top polarizer 26 are used to convert light polarization of the light beam.

The quantum dot layer 27 is disposed above the top polarizer 26, and has a plurality of quantum dot blocks 271, 272, 273 which comprise a plurality of quantum dots and are arranged in a matrix. The terms “quantum dot”, “nanodot”, “dot”, and “nanocrystal” are readily understood by the ordinarily skilled people to represent like structures and are used herein interchangeably. The quantum dots when excited by the light beam passing through the top polarizer 26 convert the light wavelength. The optical properties of the quantum dots can be determined by their particle size, chemical property or composition. The materials of the quantum dots include, but are not limited to BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI and ZnCdSe.

In this embodiment, the material of the quantum dots is ZnCdSe, whose chemical formula is Cd₁₋ₓZnₓSe, wherein x is in the range of 0.3≦x≦0.45. Preferably, x=0.38, and the material of the quantum dots is Cd_{0.62}Zn_{0.38}Se.

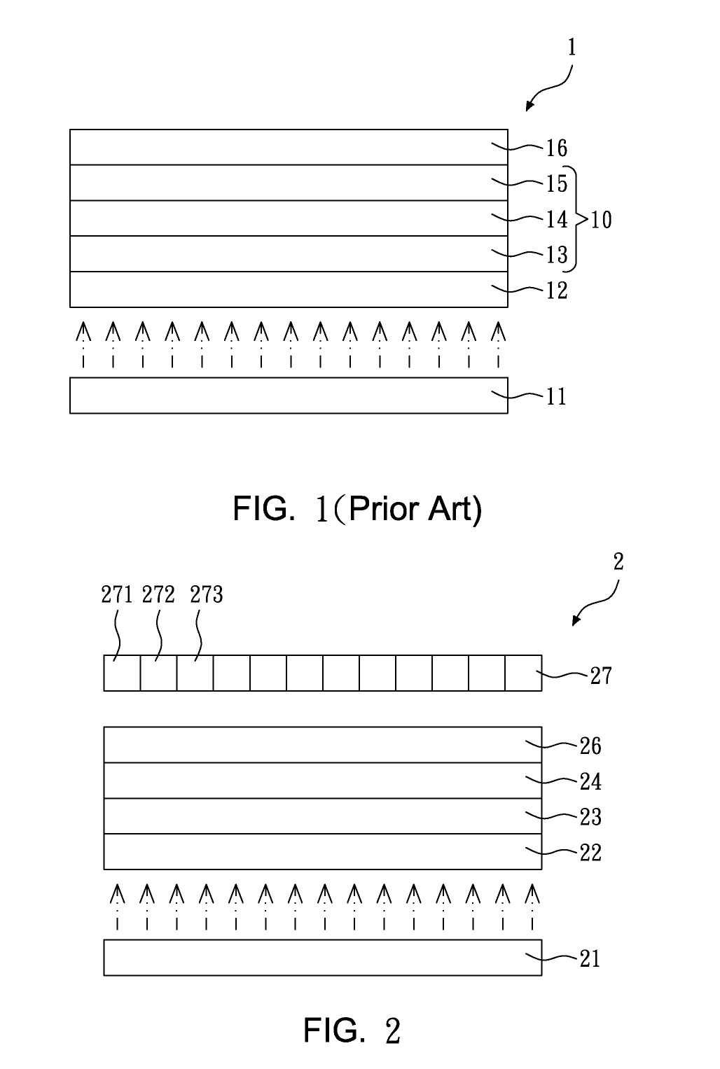

The quantum dots are of different particle sizes, or different materials, which effect the color of each pixel of the image. In this embodiment, the quantum dots comprise a first quantum dot, a second quantum dot and a third quantum dot. The first quantum dot emits red light when it is excited by the light beam, the second quantum dot emits green light when it is excited by the light beam, and the third quantum dot emits blue light when it is excited by the light beam. The quantum dots of the quantum dot blocks 271, 272, 273 can be the first quantum dot, the second quantum dot, or the third quantum dot. Therefore, the quantum dot blocks 271, 272, 273 can emit light beams with different colors, and the color filter 15 (FIG. 1) of prior art can be omitted. Compared with the luminescent efficiency of the display apparatus 1, the luminescent efficiency of the display apparatus 2 is raised, says, 50% to 80%.

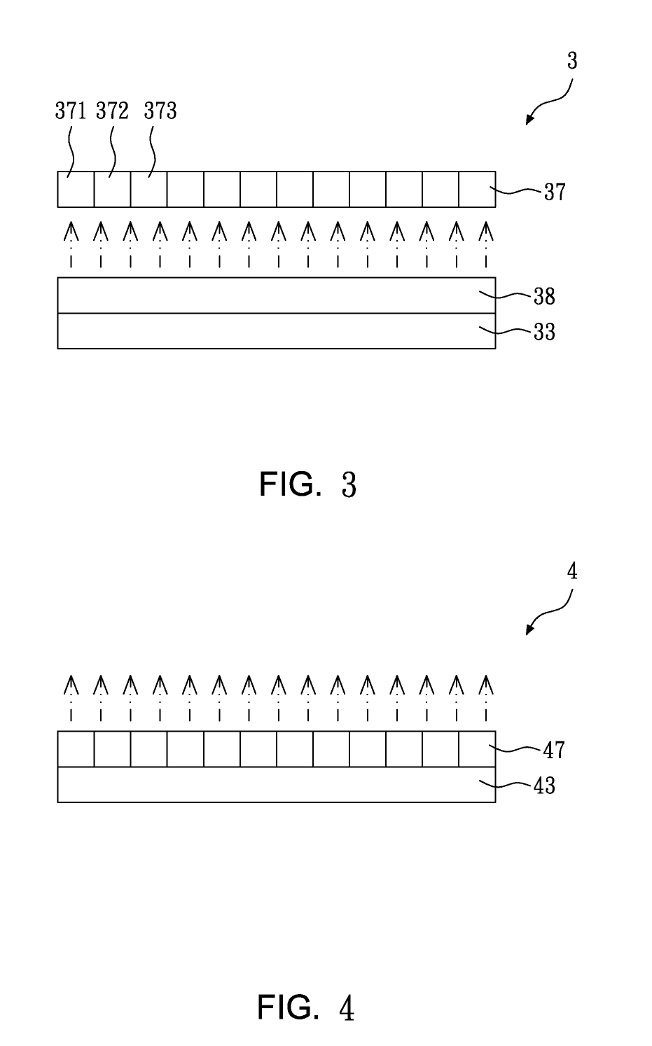

FIG. 3 shows a schematic view of a display apparatus according to a second embodiment of the present invention. The display apparatus 3 comprises an electrical controller layer 33, a light emitting layer 38 and a quantum dot layer 37. The electrical controller layer 33 has a plurality of pixels arranged in a matrix, and is electrically connected to a PCB (not shown). In this embodiment, the electrical controller layer 33 is a thin film transistor (TFT) layer which has a plurality of TFTs arranged in a matrix. That is, the pixels of the electrical controller layer 33 are the TFTs. Each of the TFTs includes a source electrode, a gate electrode and a drain electrode. The source electrode is electrically connected to a data line, the gate electrode is electrically connected to a scan line, and the drain electrode is electrically connected to a pixel electrode. The pixel electrode includes an optically transparent and electrically conductive material. Thin film transistor (TFT) layer of this embodiment can be the same as the thin film transistor (TFT) layer 23 of the first embodiment. Thin film transistor (TFT) layer of this embodiment should have a function of switch , and can be different from the thin film transistor (TFT) layer 23 of the first embodiment.

The light emitting layer 38, for example, an OLED or a PLED, is used to provide a light beam and disposed above the electrical controller layer 33. The pixels of the electrical controller layer 33 are controlled by the PCB so as to control the photoactivity of the light emitting layer 38. In one example, the light emitting layer 38 does not have any pixel structure. However, in other example, the light emitting layer 38 has a plurality of pixels arranged in a matrix, the pixels of the light emitting layer 38 correspond to the pixels of the electrical controller layer 33. The pixels of the electrical controller layer 33 control the on/off of the pixels of the light emitting layer 38.

The quantum dot layer 37 is disposed above the light emitting layer 38 to display an image, and the image has a plurality of pixels. The quantum dot layer 37 has a plurality of quantum dot blocks 371, 372, 373 which comprise a plurality of quantum dots and are arranged in a matrix. Each pixel of the electrical controller layer 33 corresponds to at least one quantum dot block 371, 372, 373. The optical properties of the quantum dots can be determined by their particle size, chemical property or composition. The materials of the quantum dots of this embodiment are the same as that of the quantum dots of the first embodiment. The quantum dots when excited by the light beam from the light emitting layer 38 convert the light wavelength. In this embodiment, the quantum dots comprise a first quantum dot ,a second quantum dot and a third quantum dot. The first quantum dot emits red light when it is excited by the light beam, the second quantum dot emits green light when it is excited by the light beam, and the third quantum dot emits blue light when it is excited by the light beam. The quantum dots of the quantum dot blocks 371, 372, 373 can be the first quantum dot, the second quantum dot, or the third quantum dot. The quantum dot blocks 371, 372, 373 can emit light beams with different colors, therefore, the bottom polarizer 12, the thin film transistor (TFT) layer 13, the liquid crystal layer 14, the color filter layer 15 and the top polarizer 16 (FIG. 1) of prior art can be omitted. Compared with the luminescent efficiency of the display apparatus 1, the luminescent efficiency of the display apparatus 3 is raised, says, 50% to 80%.

FIG. 4 shows a schematic view of a display apparatus according to a third embodiment of the present invention. The display apparatus 4 comprises an electrical controller layer 43 and a quantum dot layer 47. The electrical controller layer 43 has a plurality of pixels arranged in a matrix, and is electrically connected to a PCB (not shown). For example, the electrical controller layer 43 is a thin film transistor (TFT) layer which has a plurality of TFTs arranged in a matrix. That is, the pixels of the electrical controller layer 43 are the TFTs. Each of the TFTs includes a source electrode, a gate electrode and a drain electrode. The source electrode is electrically connected to a data line, the gate electrode is electrically connected to a scan line, and the drain electrode is electrically connected to a pixel electrode. The pixel electrode includes an optically transparent and electrically conductive material. Thin film transistor (TFT) layer of this embodiment can be the same as the thin film transistor (TFT) layer 23 of the first embodiment. Thin film transistor (TFT) layer of this embodiment should have a function of switch, and can be different from the thin film transistor (TFT) layer 23 of the first embodiment.

The quantum dot layer 47 is attached to the top surface of the electrical controller layer 43 to display an image, and the image has a plurality of pixels. The quantum dot layer 47 has a plurality of quantum dot blocks which comprise quantum dots and are arranged in a matrix. Each pixel of the electrical controller layer 43 corresponds to at least one quantum dot block. The quantum dots have property of electricity-to-light conversion, thus they can convert electricity into light beams with different colors. The pixels of the electrical controller layer 43 are controlled by a PCB (not shown). As the electrical controller layer 43 transmits electricity to the quantum dot layer 47, the pixels of the electrical controller layer 43 can control the photoactivity of the quantum dots of the quantum dot layer 47. The optical properties of the quantum dots can be determined by their particle size, chemical property or composition. The materials of the quantum dots of the quantum dot layer 47 are the same as those of the quantum dots of the first embodiment. The quantum dots can emit light beams of different colors, determined by the particle size or other properties of the quantum dots, when they are excited by the pixels of the electrical controller layer 43. The optical properties of the quantum dots can be determined by their particle size, chemical property or composition. The quantum dots are of different particle sizes, or different materials, so as to determine the color of each pixel of the image.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined by the appended claims.

What is claimed is:

1. A display apparatus, comprising:
a light source, used to provide a light beam;
a thin film transistor (TFT) layer, having a plurality of TFTs arranged in a matrix;
a liquid crystal layer, having a plurality of liquid crystal molecules, and disposed on the thin film transistor (TFT) layer, and the TFTs being used to control the liquid crystal molecules;
a bottom polarizer, attached to a bottom surface of the thin film transistor (TFT) layer, and being used to convert light polarization of the light beam;
a top polarizer, attached to a top surface of the liquid crystal layer, and being used to convert light polarization of the light beam, wherein the bottom polarizer, the thin film transistor (TFT) layer, the liquid crystal layer and the top polarizer are disposed above the light source to display an image which comprises a plurality of pixels; and
a quantum dot layer, disposed above the top polarizer, and having a plurality of quantum dot blocks which comprise quantum dots and are arranged in a matrix, wherein the quantum dots when excited by light beam passing through the top polarizer convert the light wavelength so as to determine the color of each pixel of the image.

2. The display apparatus as claimed in claim 1, wherein the light source is at least one LED or CCFL, or a back light module.

3. The display apparatus as claimed in claim 1, wherein the materials of the quantum dots are selected from a group consisting of BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI and ZnCdSe.

4. The display apparatus as claimed in claim 1, wherein the material of the quantum dots is Cd₁₋ₓZnₓSe, and wherein x is in the range of 0.3≦x≦0.45.

5. The display apparatus as claimed in claim 4, wherein the material of the quantum dots is Cd_{0.62}Zn_{0.38}Se.

6. The display apparatus as claimed in claim 1, wherein the quantum dots comprise a first quantum dot, a second quantum dot and a third quantum dot, the first quantum dot emits red light when excited by the light beam, the second quantum dot emits green light when excited by the light beam, and the third quantum dot emits blue light when excited by the light beam.

7. A display apparatus, comprising:
an electrical controller layer, having a plurality of pixels arranged in a matrix;
a light emitting layer, used to provide a light beam, the light emitting layer being disposed above the electrical controller layer, and controlled by the electrical controller layer; and
a quantum dot layer, disposed above the light emitting layer to display an image, which comprises a plurality of pixels, the quantum dot layer having a plurality of quantum dot blocks which comprise quantum dots and are arranged in a matrix, wherein each pixel of the electrical controller layer corresponds to at least one quantum dot block, the quantum dots when excited by the light beam convert the light wavelength so as to determine the color of each pixel of the image.

8. The display apparatus as claimed in claim 7, wherein the light emitting layer is an OLED or a PLED.

9. The display apparatus as claimed in claim 7, wherein the electrical controller layer is a the thin film transistor (TFT) layer.

10. The display apparatus as claimed in claim 7, wherein the light emitting layer has a plurality of pixels arranged in a matrix, the pixels of the light emitting layer correspond to the pixels of the electrical controller layer, and the pixels of the electrical controller layer control the on/off of the pixels of the light emitting layer.

11. The display apparatus as claimed in claim 7, wherein the materials of the quantum dots are selected from a group consisting of BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI and ZnCdSe.

12. The display apparatus as claimed in claim 7, wherein the material of the quantum dots is Cd₁₋ₓZnₓSe, wherein x is in the range of 0.3≦x≦0.45.

13. The display apparatus as claimed in claim 12, wherein the material of the quantum dots is Cd_{0.62}Zn_{0.38}Se.

14. The display apparatus as claimed in claim 7, wherein the quantum dots comprise a first quantum dot, a second quantum dot and a third quantum dot, the first quantum dot emits red light when excited by the light beam, the second quantum dot emits green light when excited by the light beam, and the third quantum dot emits blue light when excited by the light beam.

15. A display apparatus, comprising:
an electrical controller layer, having a plurality of pixels arranged in a matrix; and
a quantum dot layer, disposed above the electrical controller layer to display an image which comprise a plurality of pixels, the quantum dot layer having a plurality of quantum dot blocks which comprise quantum dots and are arranged in a matrix, wherein each pixel of the electrical controller layer corresponds to at least one quantum dot block, the quantum dots emit light when excited by the pixels of the electrical controller layer so as to determine the color of each pixel of the image.

16. The display apparatus as claimed in claim 15, wherein the electrical controller layer is a the thin film transistor (TFT) layer.

17. The display apparatus as claimed in claim 15, wherein the materials of the quantum dots are selected from a group consisting of BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI and ZnCdSe.

18. The display apparatus as claimed in claim 15, wherein the material of the quantum dots is Cd₁₋ₓZnₓSe, wherein x is in the range of 0.3≦x≦0.45.

19. The display apparatus as claimed in claim 18, wherein the material of the quantum dots is Cd_{0.62}Zn_{0.38}Se.
